(19) United States
(12) Patent Application Publication
(10) Pub. No.: US 2004/0180482 A1
(43) Pub. Date: Sep. 16, 2004

(54) Semiconductor device and manufacturing method thereof

(76) Inventor: Takafumi Noda, Sakata - shi (JP)

Correspondence Address: HARNESS, DICKEY & PIERCE, P.L.C., P.O. BOX 828, BLOOMFIELD HILLS, MI, 48303, US

(21) Appl. No.: 10/756,805

(22) Filed: Jan. 13, 2004

(30) Foreign Application Priority Data
Jan. 14, 2003 (JP) 2003-005859

(51) Int. Cl. H01L 29/76; H01L 21/336

(52) U.S. Cl. 438/197; 257/288

(57) ABSTRACT

A semiconductor device is provided that includes a gate oxide film provided on an n-type silicon substrate, a gate electrode provided on the gate oxide film, and a source region and a drain region formed in the silicon substrate at two sides of the gate electrode. The source and the drain regions are composed of P⁻ layers provided in the silicon substrate along the two sides of the gate electrode by introducing B⁺ ions, and P⁺ layers provided, in the P⁻ layers of the silicon substrate at the sides spaced apart from the gate electrode. The P⁺ layers are in contact with the respective P⁻ layers. In addition, N⁺ ions for suppressing the diffusion of the B⁺ ions into the silicon substrate are introduced in the P⁻ layers.

### RELATED APPLICATIONS

The entire disclosure of Japanese Patent Application No. 2003-005859 filed Jan. 14, 2003 is incorporated by reference.

### BACKGROUND OF THE INVENTION

1. Technical Field of the Invention

The present invention relates to semiconductor devices and manufacturing methods thereof, and more specifically, relates to a semiconductor device and a manufacturing method thereof, which are each suitably applied to a low power consumption LSI including pMOS transistors in the 0.13 micron generation and beyond.

2. Description of the Related Art

In recent years, concomitant with the increasing trend to make fine and highly integrated semiconductor devices, the gate length of a MOS transistor formed on a semiconductor substrate has been reduced to a submicron level. In a MOS transistor at a submicron level, an LDD structure has been widely used.

FIG. 7 is a cross-sectional view showing a structural example of a semiconductor device 90 according to a conventional example. As shown in FIG. 7, in this semiconductor device 90, a pMOS transistor 95 is formed on an n-type silicon substrate 1. In addition, as shown in FIG. 7, an LDD structure is used in this pMOS transistor 95. That is, boron (B⁺) ions are selectively implanted in the silicon substrate 1 and are then thermally diffused, thereby forming lightly doped source and drain extension layers 92 and highly doped source and drain layers 93.

By using this LDD structure, the source and the drain regions of the PMOS transistor 95 can be formed to have a small thickness while suppressing an increase in electrical resistance of the regions mentioned above. Hence, even when the semiconductor device 90 is reduced to a submicron level, the short channel effect, such as punch through or leak current, can be suppressed to a certain extent.

According to the semiconductor device 90 of the conventional example, the LDD structure was used for the pMOS transistor 95, and the lightly doped source and drain extension layers 92 and the highly doped source and drain layers 93 were provided for the silicon substrate 1.

However, the source and the drain extension layers 92 and the source and the drain layers 93 are formed by implanting boron (B⁺) ions into the silicon substrate 1. The B⁺ ions have a high diffusion coefficient in the silicon substrate 1.

Accordingly, in a thermal processing step for a semiconductor device, the source and the drain extension layers 92 are diffused in the lateral and the depth directions, and as a result, there has been a problem in that an effective channel length (Leff′) with respect to the gate length is considerably decreased.

In particular, when the pMOS transistor 95 (hereinafter referred to as “field effect transistor” in some cases) is designed so that the gate length thereof is reduced to approximately 0.13 μm, the decrease in effective channel length caused by the diffusion of the B⁺ ions cannot be ignored, and as a result, the short channel effect, such as frequent punch through occurrence or increase in leak current, may become significant in some cases. When the short channel effect becomes significant, it becomes difficult to perform microfabrication in the 0.13 micron generation and beyond.

Accordingly, the present invention was made to solve the problems of the conventional technique described above, and an object of the present invention is to provide a semiconductor device and a manufacturing method thereof, in which the decrease in effective channel length of a field effect transistor can be suppressed to a certain extent and in which progress in microfabrication of semiconductor devices can be further achieved.

### SUMMARY

In order to achieve the object described above, a semiconductor device of the present invention comprises: a gate insulating film provided on a semiconductor layer; a gate electrode provided on this gate insulating film; and a source and a drain region provided in the semiconductor layer at two sides of the gate electrode, wherein the source and the drain regions comprise: first impurity diffusion layers formed of a specific impurity introduced in the semiconductor layer at the two sides of the gate electrodes; and second impurity diffusion layers provided in the semiconductor layer at the opposite sides of the first impurity diffusion layers from the gate electrode and being in contact with the first impurity diffusion layers, and the first impurity diffusion layers comprise a diffusion suppression impurity for suppressing the diffusion of the specific impurity into the semiconductor layer.

According to the semiconductor device of the present invention, since the impurity for suppressing the diffusion of the specific impurity is introduced in the first impurity diffusion layers which form the source and the drain regions, the diffusion of the first impurity diffusion layers in the lateral direction and the depth direction can be suppressed. Hence, the decrease in effective channel length caused by the diffusion of the first impurity diffusion layers can be suppressed to a certain extent, and as a result, progress in microfabrication can be further achieved.

In the semiconductor device of the present invention, the diffusion suppression impurity may be introduced in the semiconductor layer under the gate electrode.

According to the above, since the diffusion of the specific impurity from the first impurity diffusion layers into the semiconductor layer under the gate electrode can also be suppressed by the semiconductor layer side under the gate electrode, the decrease in effective channel length can be further suppressed.

A method for manufacturing a semiconductor device of the present invention comprises: a step of forming a gate insulating film on a semiconductor layer; a step of forming a gate electrode on the gate insulating film; a step of introducing a diffusion suppression impurity for suppressing the diffusion of a specific impurity into the semiconductor layer using the gate electrode as a mask; a step of introducing the specific impurity into the semiconductor layer in which the diffusion suppression impurity is introduced to form first impurity diffusion layers; and a step of introducing an optional impurity into regions of the first impurity diffusion layers of the semiconductor layer to form second impurity diffusion layers, the regions each being spaced apart from the gate electrode by a predetermined distance.

According to the method for manufacturing a semiconductor device of the present invention, the spreading of the first impurity diffusion layers in the lateral direction and the depth direction can be suppressed. As a result, the decrease in effective channel length can be suppressed to a certain extent.

Another method for manufacturing a semiconductor device of the present invention comprises: a step of introducing a diffusion suppression impurity for suppressing the diffusion of a specific impurity into a semiconductor layer and forming a gate insulating film on the semiconductor layer; a step of forming a gate electrode on the gate insulating film; a step of introducing the specific impurity into the semiconductor layer using the gate electrode as a mask to form first impurity diffusion layers; and a step of introducing an optional impurity into regions of the first impurity diffusion layers of the semiconductor layer to form second impurity diffusion layers, the regions each being spaced apart from the gate electrode by a predetermined distance.

According to the above method for manufacturing a semiconductor device of the present invention, since the diffusion suppression impurity is also introduced in the semiconductor layer under the gate electrode, the diffusion of the specific impurity can also be suppressed by the semiconductor layer side under the gate electrode. As a result, the decrease in effective channel length can be further suppressed.

In the above method for manufacturing a semiconductor device of the present invention, the step of introducing a diffusion suppression impurity into a semiconductor layer and forming a gate insulating film thereon may be a step of forming a gate insulating film containing the diffusion suppression impurity on the semiconductor layer so as to diffuse the diffusion suppression impurity into the semiconductor layer.

According to the above manufacturing method of a semiconductor device of the present invention, since the step of introducing a diffusion suppression impurity into a semiconductor layer and the step of forming a gate insulating film thereon are performed by one step of forming the gate insulating film containing the diffusion suppression impurity on the semiconductor layer, the number of steps can be decreased.

### BRIEF DESCRIPTION OF THE DRAWINGS

FIG. 1 is a cross-sectional view showing a structural example of a semiconductor device 100 according to a first embodiment of the present invention.

FIGS. 2(A)-(C) include schematic views showing steps of a manufacturing method of the semiconductor device 100.

FIGS. 3(A)-(C) include schematic views showing steps of a manufacturing method of the semiconductor device 100.

FIG. 4 is a cross-sectional view showing a structural example of a semiconductor device 200 according to a second embodiment of the present invention.

FIGS. 5(A)-(C) include schematic views showing steps of a manufacturing method of the semiconductor device 200.

FIGS. 6(A)-(C) include schematic views showing steps of a manufacturing method of the semiconductor device 200.

FIG. 7 is a cross-sectional view showing a structural example of a semiconductor device 90 according to a conventional example.

### DETAILED DESCRIPTION

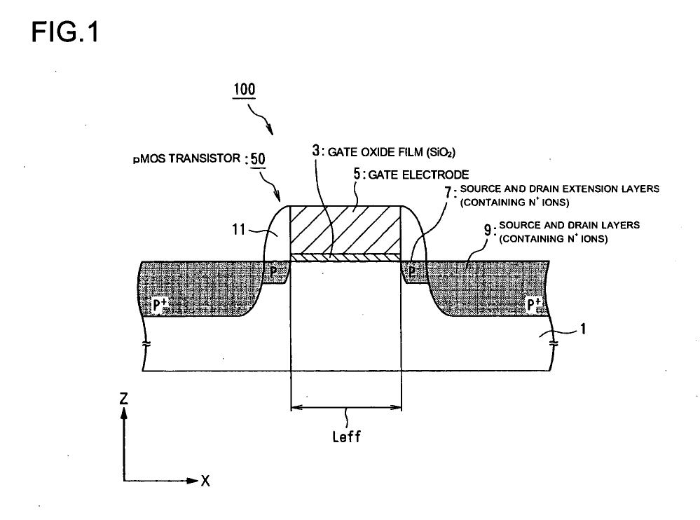

Hereinafter, embodiments of the present invention will be described with reference to drawings. FIG. 1 is a cross-sectional view of a structural example of a semiconductor device 100 of a first embodiment according to the present invention.

### First Embodiment

The semiconductor device 100 shown in FIG. 1 is, for example, an LSI composed of a plurality of pMOS transistors 50 each having a gate length of 0.13 μm provided on an n-type silicon substrate 1. This semiconductor device 100 is a device suitably provided for an electronic apparatus, such as a digital camera or a notebook personal computer, which is particularly desired to have low power consumption properties.

As shown in FIG. 1, this pMOS transistor 50 has an LDD (Lightly Doped Drain) structure and is formed of the n-type silicon substrate 1, a gate oxide film 3 provided on this silicon substrate 1, a gate electrode 5 provided on this gate oxide film 3, p-type source and drain extension layers (source and drain extensions) 7 provided in the silicon substrate 1 at two sides of the gate electrode 5 (i.e., adjacent the projected boundary of the gate electrode), and p-type source and drain layers 9 provided in the silicon substrate 1 at the respective sides of the source and the drain extension layers 7 spaced apart from the gate electrode 5, the p-type source and drain layers 9 being in contact with (i.e., abutting) the source and drain extension layers 7, respectively.

Hereinafter, the source and the drain extension layers 7 are referred to as p⁻ layers 7, and the source and the drain layers 9 are referred to as p⁺ layers 9. In the pMOS transistor 50, the source and the drain regions are formed of the p⁻ layers 7 and the p⁺ layers 9. In addition, an impurity for suppressing diffusion is introduced in these p⁻ layers 7 and p⁺ layers 9.

In FIG. 1, the silicon substrate 1 is formed, for example, of single crystal silicon. A small amount of an impurity such as phosphorus is added to this silicon substrate 1 to form an n-type substrate. In addition, the gate oxide film 3 is a silicon oxide film (SiO₂) formed by thermally oxidizing this silicon substrate 1 in an oxygen (O₂) atmosphere. The thickness of this gate oxide film 3 is, for example, approximately 100 Å.

As shown in FIG. 1, the gate electrode 5 is provided on the gate oxide film 3. This gate electrode 5 is formed, for example, of polycrystal silicon and a small amount of phosphorus added thereto. The surface of this gate electrode 5 is covered with an oxide film, and in particular, sidewall insulating films, which are called sidewalls, are provided on the sidewall portions of the gate electrode 5. In FIG. 1, the sidewalls 11 are each formed, for example, of a silicon oxide film.

The p⁻ layers 7 are formed by introducing a specific p-type impurity into the silicon substrate 1. The specific impurity is, for example, boron (B⁺) ions. Although described later in detail, the p⁻ layers 7 are formed by introducing B⁺ ions into the silicon substrate 1 using the gate electrode 5 as a mask prior to the formation of the sidewalls 11, and then performing annealing in a nitrogen atmosphere.

The p⁺ layers 9 are formed by introducing an optional p-type impurity into the silicon substrate 1. This optional impurity is, for example, B⁺ ions. Although described later in detail, the p⁺ layers 9 are formed by introducing B⁺ ions into the p⁻ layers 7 using the gate electrode 5 and the sidewalls 11 as a mask, and then performing annealing in a nitrogen atmosphere. Hence, the impurity concentration of the p⁺ layer 9 is higher than that of the p⁻ layer 7.

As described above, the pMOS transistor 50 has an LDD structure, and in the state in which the electrical resistance of the entire source and drain regions (p⁻ layers 7 and p⁺ layers 9) is controlled at a low level, a shallow diffusion layer of the p⁻ layer 7 in contact with the channel is formed. Accordingly, the short channel effect can be suppressed, and hence the gate electrode length of the pMOS transistor can be reduced to a submicron level.

Furthermore, in this PMOS transistor 50, nitrogen (N⁺) ions, which are an example of an impurity for suppressing diffusion, are introduced in the p⁻ layers 7 and the p⁺ layers 9. In general, it has been known that B⁺ ions and N⁺ ions diffuse through interstitial Si (point defect) of silicon (Si). When present in Si, N⁺ ions diffuse through point defects faster than B⁺ ions.

Accordingly, when N⁺ ions are introduced in the p⁻ layers 7, the diffusion of the B⁺ ions forming the p⁻ layers 7 in the lateral direction (X-Y direction) and the depth direction (Z direction) can be suppressed by the N⁺ ions to a certain extent. Hence, the decrease in effective channel length (Leff) caused by the diffusion of the p⁻ layers 7 can be suppressed to a certain extent. In addition, ultra shallow junctions between the source and drain extension layers (p⁻ layers) 7 and the channel region can also be realized. As a result, progress in microfabrication of semiconductor devices in the 1.3 micron generation or beyond can be achieved.

In this first embodiment, the n-type silicon substrate 1 corresponds to the semiconductor layer of the present invention, and the gate oxide film 3 corresponds to the gate insulating film of the present invention. In addition, the source and the drain extension layers (p⁻ layers) 7 correspond to the first impurity diffusion layers of the present invention, and the source and the drain layers (p⁺ layers) 9 correspond to the second impurity diffusion layers of the present invention. Furthermore, the specific impurity corresponds to B⁺ ions, and the impurity for suppressing diffusion corresponds to N⁺ ions.

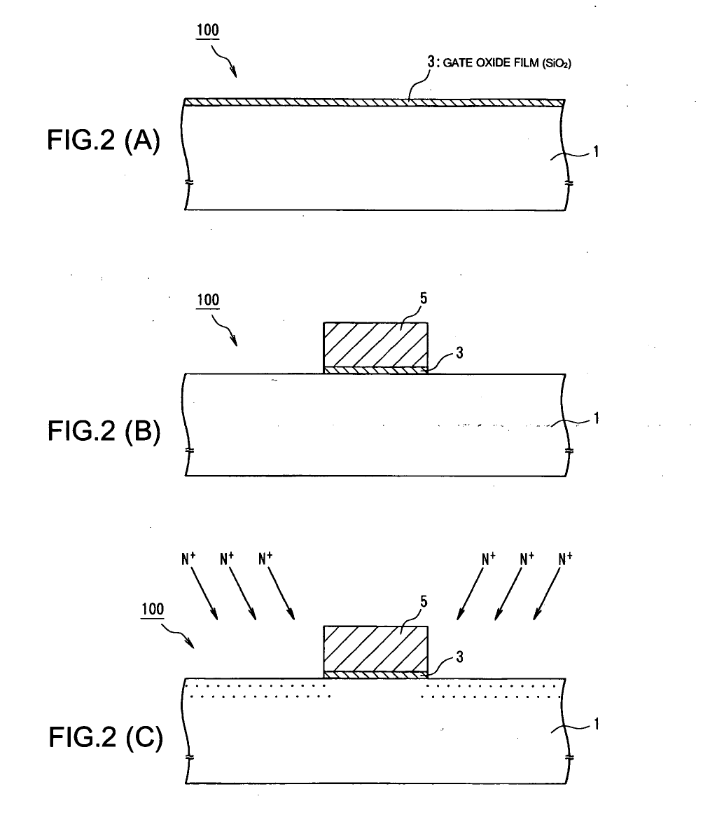

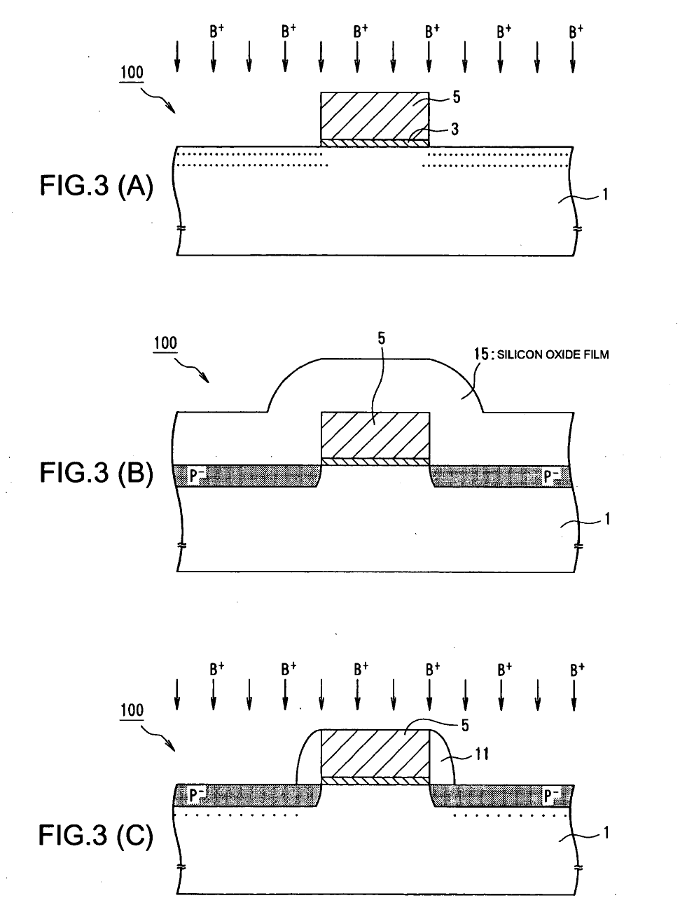

Next, a method for manufacturing the semiconductor device 100 of the first embodiment according to the present invention will be described. FIGS. 2(A) to 3(C) show steps of the method for manufacturing the semiconductor device 100. In this embodiment, a case will be described in which the semiconductor device 100 shown in FIG. 1 is formed by the steps shown in FIGS. 2(A) to 3(C) in that order.

In FIG. 2(A), the silicon substrate 1 is first prepared. Next, a well diffusion layer and an element isolation layer, not shown in the figure, are sequentially formed in the silicon substrate 1. Subsequently, the surface of this silicon substrate 1 is thermally oxidized in an oxygen atmosphere to form the gate oxide film 3, the thickness thereof being approximately 100 Å. Furthermore, on this gate oxide film 3, a polycrystal silicon film is formed. The formation of the polycrystal silicon film is performed, for example, by CVD. Next, a predetermined amount of an impurity such as phosphorus is ion-implanted into this polycrystal silicon film so as to obtain a predetermined conductivity.

Next, this polycrystal silicon film is patterned by a photolithographic technique and an etching technique, and as shown in FIG. 2(B), the gate electrode 5 is formed on the gate oxide film 3 located in a position at which the channel is to be formed. In this step, the etching technique is dry etching such as RIE (Reactive Ion Etching). After the gate electrode 5 shown in FIG. 2(B) is formed, this silicon substrate 1 is thermally oxidized to form a thin silicon oxide film (not shown) on the surface of the gate electrode 5.

Next, as shown in FIG. 2(C), nitrogen (N⁺) ions are ion-planted into a shallow region of the silicon substrate 1 using this gate electrode 5 as a mask. The implantation energy of the N⁺ ions is, for example, approximately 10 KeV, and the dose is, for example, approximately 2×10¹⁵/cm². In this step, as shown in FIG. 2(C), the N⁺ ions are preferably implanted at an angle, for example, of 30° with respect to the silicon substrate 1. Accordingly, the N⁺ ions can be provided in the silicon substrate 1 under the gate electrode 5 at which the channel region is to be formed.

Next, as shown in FIG. 3(A), B⁺ ions for forming the P⁻ layers 7 are implanted into the shallow regions of the silicon substrate 1 in which N⁺ ions have been implanted. The implantation of the B⁺ ions is performed using the gate electrode 5 as a mask. In this step, the implantation energy of the B⁺ ions is, for example, approximately 1 KeV, and the dose is, for example, approximately 2×10¹⁵/cm². In addition, the implantation angle of the B⁺ ions is, for example, approximately 0°.

In addition, before or after this B⁺ ion implantation step, an impurity such as phosphorus (P⁺ ions) may be implanted in this silicon substrate 1 as a measure against punch through. Accordingly, a layer (not shown) for preventing punch through can be formed.

Next, as shown in FIG. 3(B), a silicon oxide film 15 is formed on the silicon substrate 1 by CVD. Subsequently, this silicon oxide film 15 is etched back by anisotropic dry etching, thereby forming the sidewalls 11 on the sidewall portions of the gate electrode 5 as shown in FIG. 3(C).

Next, as shown in FIG. 3(C), B⁺ ions for forming the P⁺ layers are implanted into a deep region of the silicon substrate 1 using the gate electrode 5 provided with the sidewalls 11 as a mask. In this step of implanting B⁺ ions, the implantation energy is, for example, approximately 8 KeV, and the dose is, for example, approximately 2×10¹⁵/cm². In addition, the implantation angle of the B⁺ ions is, for example, approximately 0°.

Subsequently, the silicon substrate 1 in which the B⁺ ions have been implanted is processed by heat treatment (annealing) in an inert gas atmosphere containing nitrogen (N₂) or the like, so that the N⁺ ions and the B⁺ ions implanted in the silicon substrate 1 are diffused while being activated. In this annealing step, by the nitrogen (N⁺) ions implanted in the silicon substrate 1, the diffusion of the boron (B⁺) ions in the lateral and the depth directions is suppressed. In this annealing step, in regions of the P⁻ layers 7 located at positions spaced apart from the gate electrode 5 by a predetermined distance, the P⁺ layers 9 (see FIG. 1) are formed.

After the annealing step, interlayer insulating films, plug electrodes, metal wires, and the like, which are not shown in the figure, are formed, thereby forming the semiconductor device 100 shown in FIG. 1. In the method for manufacturing this semiconductor device 100, since the nitrogen (N⁺) ions are implanted into the shallow region of the silicon substrate 1 using the gate electrode 5 as a mask, the diffusion of the P⁻ layers 7 formed in the silicon substrate 1 in the lateral and the depth directions can be suppressed.

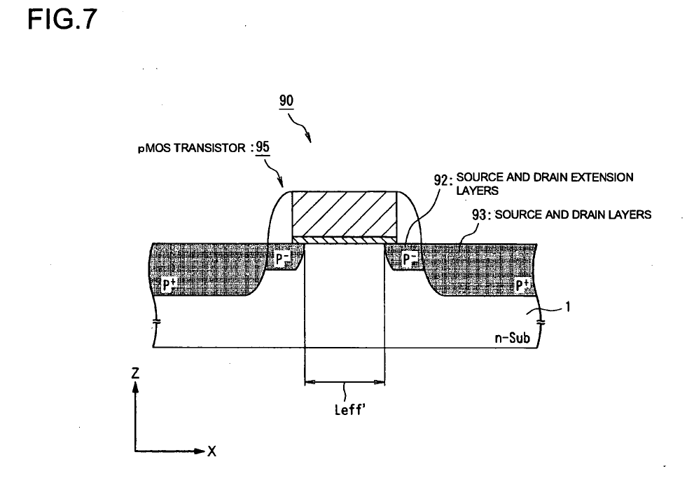

That is, compared to the pMOS transistor 95 according to the conventional style shown in FIG. 7, the decrease in effective channel length caused by the diffusion of the P⁻ layers can be suppressed (Leff′<Leff). In addition, at the same time as described above, the increase in depth Xⱼ of a diffusion layer of each of the P⁻ layers 7 can also be suppressed. Accordingly, the short channel effect such as punch through and gate leak can be suppressed to a certain extent, and hence progress in microfabrication of semiconductor devices can be further achieved.

### Second Embodiment

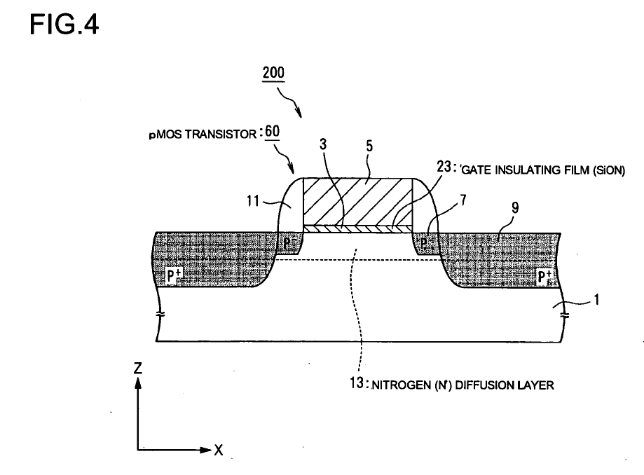

Next, a semiconductor device 200 of a second embodiment according to the present invention will be described. FIG. 4 is a cross-sectional view showing a structural example of the semiconductor device 200. In this embodiment, a case will be described in which nitrogen is also introduced into the channel region located under the gate electrode 5 of the semiconductor device 100 shown in FIG. 1. The remaining conditions are equivalent to those described in the first embodiment. Accordingly, the same reference numerals of the semiconductor device 100 designate elements shown in FIG. 4 having the same structures and functions as those of the semiconductor device 100, and a description thereof is omitted.

As shown in FIG. 4, this semiconductor device 200 is, for example, a ULSI composed of a plurality of pMOS transistors 60 each having a gate length of 0.13 μm provided on the n-type silicon substrate 1. This pMOS transistor 60 has an LDD structure and is formed of the n-type silicon substrate 1, a gate insulating film 23 provided on this silicon substrate 1, the gate electrode 5 provided on this gate insulating film 23, the p⁻ layers 7 provided in the silicon. substrate 1 at two sides of the gate electrode 5 (i.e., outwardly bordering a projected perimeter of the gate electrode), and the p⁺ layers 9 provided in the silicon substrate 1 adjacent to the p⁻ layers 7.

In this embodiment, the gate insulating film 23 is different from that of the semiconductor device 100 shown in FIG. 1 and is, for example, a silicon oxynitride film (SiON) containing a given amount of nitrogen (N⁺) ions. In the semiconductor device 200 shown in FIG. 4, by SiON formed on the silicon substrate 1, N⁺ ions are diffused into a shallow region of the silicon substrate 1. That is, in the semiconductor device 200, N⁺ ions are introduced in the p⁻ layers 7, the p⁺ layers 9, and the shallow region of the silicon substrate 1 under the gate electrode 5. Hereinafter, the shallow region of the silicon substrate 1 into which the N⁺ ions are diffused is also called a nitrogen diffusion layer 13.

In the semiconductor device 200 shown in FIG. 4, this nitrogen diffusion layer 13 and the p⁻ layers 7 overlap each other, and hence the diffusion of B⁺ ions in each P⁻ layer 7 in the lateral (X-Y direction) and the depth (Z direction) directions can be suppressed by the N⁺ ions. In addition, in this semiconductor device 200, the silicon substrate 1 under the gate electrode 5, that is, the channel region, also overlaps the nitrogen diffusion layer 13, and hence the diffusion of the B⁺ ions from each P⁻ layer 7 into the channel region can be suppressed by the channel region side. Accordingly, in this semiconductor device 200, the diffusion of the P⁻ layers 7 can be more effectively suppressed than that of the semiconductor device 100, and hence the decrease in effective channel length can be further suppressed.

As described above, in this semiconductor device 200, the silicon oxynitride film (SiON) is used for the gate insulating film 23. This silicon oxynitride film (SiON) has a high dielectric constant as compared to that of a silicon oxide film (SiO₂), and hence performance of the pMOS transistor 60 can be improved.

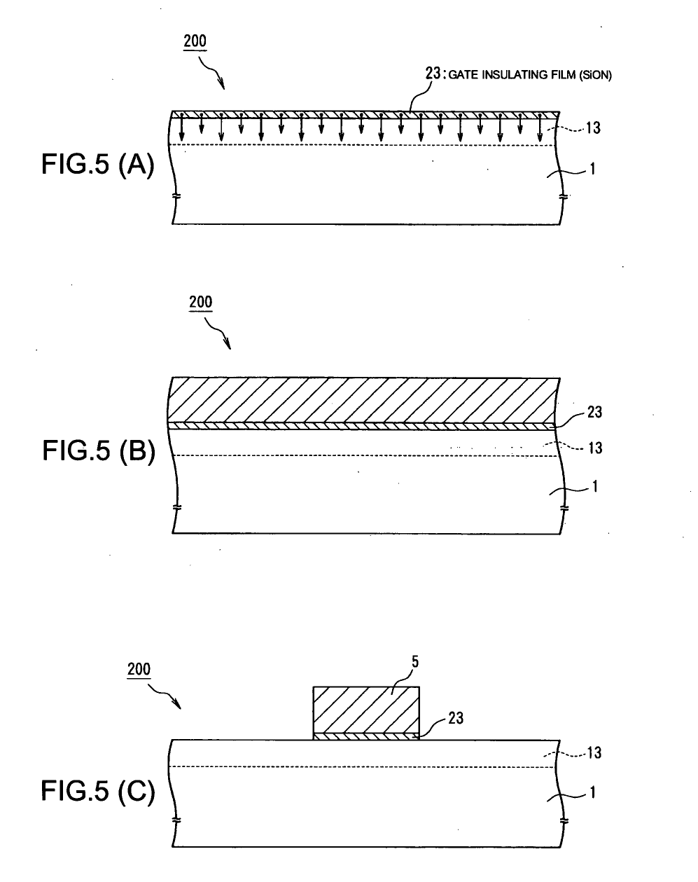

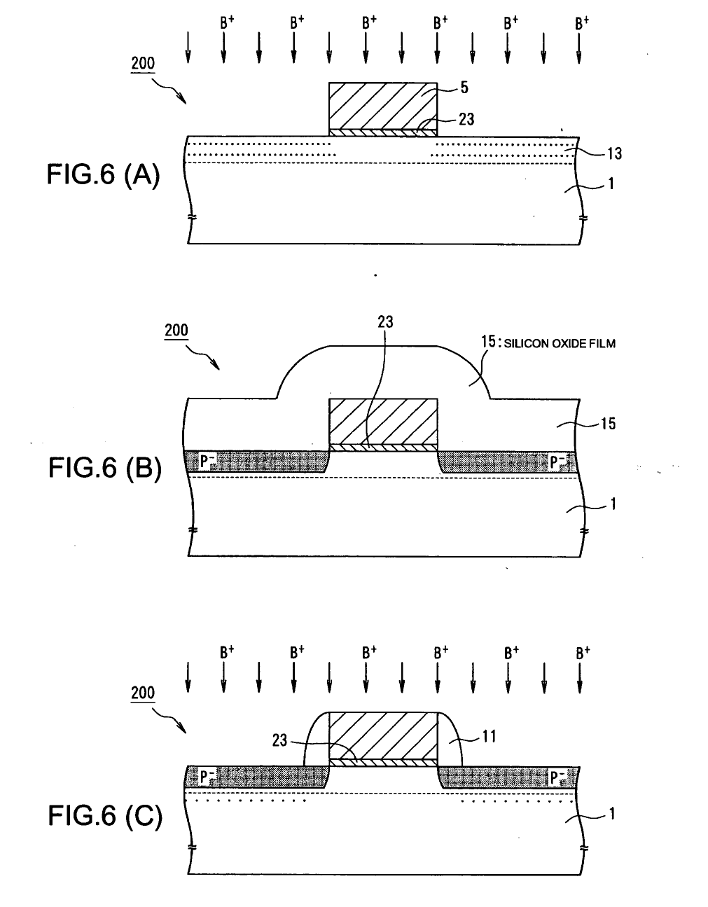

Next, a method for manufacturing the semiconductor device 200 of the second embodiment according to the present invention will be described. FIGS. 5(A) to 6(C) show steps of the method for manufacturing the semiconductor device 200. In this embodiment, a case will be described in which the semiconductor device 200 shown in FIG. 4 is formed by the steps shown in FIGS. 5(A) to 6(C) in that order.

In FIG. 5(A), the silicon substrate 1 is first prepared. Next, a well diffusion layer and an element isolation layer, which are not shown in the figure, are formed in the silicon substrate 1. Subsequently, this silicon substrate 1 is thermally oxidized in a mixed gas atmosphere containing oxygen (O₂) and nitrogen (N₂) to form the gate insulating film 23 (SiON), the thickness thereof being approximately 100 Å.

In the step described above, the N content is approximately 4%, and as a method for introducing nitrogen into a SiO₂ film, thermal oxidation may be performed alone or in combination with lamp annealing. The oxidation temperature is, for example, approximately 900° C. In this step, as shown by arrows in FIG. 5(A), nitrogen (N⁺) ions in the gate insulating film (SiON) 23 are thermally diffused to the silicon substrate 1 side, and as a result, the nitrogen diffusion layer 13 is formed in a shallow region of the silicon substrate 1.

Next, as shown in FIG. 5(B), a polycrystal silicon film is formed on this gate insulating film 23. Then, a predetermined amount of an impurity such as phosphorus is ion-implanted into this polycrystal silicon film, thereby obtaining predetermined conductivity. In addition, this polycrystal silicon film is patterned, thereby forming the gate electrode 5 on the gate insulating film 23 in a region at which the channel is to be formed, as shown in FIG. 5(C).

After the gate electrode 5 shown in FIG. 5(C) is formed, this silicon substrate 1 is thermally oxidized to form a thin silicon oxide film (not shown) on the surface of the gate electrode 5. Next, as shown in FIG. 6(A), B⁺ ions for forming the P⁻ layers are implanted in the silicon substrate 1 in which the N⁺ ions have been implanted already using the gate electrode 5 as a mask. Subsequently, as shown in FIG. 6(B), the silicon oxide film 15 is formed on this silicon substrate 1 by CVD.

Subsequently, this silicon oxide film 15 is etched back by anisotropic dry etching, thereby forming the sidewalls 11. Next, B⁺ ions for forming the P⁺ layers are implanted in the silicon substrate 1 using the gate electrode 5 provided with the sidewalls 11 as a mask. Next, the silicon substrate 1 in which the B⁺ ions have been implanted is processed by heat treatment (annealing) in an inert gas atmosphere containing nitrogen (N₂) or the like, so that the N⁺ ions and the B⁺ ions implanted in the silicon substrate 1 are diffused while being activated.

In this annealing step, by the nitrogen (N⁺) ions diffused into the silicon substrate 1 from the gate insulating film (SiON) 23, the diffusion of the B⁺ ions in the lateral and the depth directions is suppressed. In addition, the N⁺ ions are also introduced in the channel region of the pMOS transistor 60, and hence diffusion of the B⁺ ions from the P⁻ layers 7 into the channel region can also be suppressed by the inside thereof.

In this annealing step, in regions of the P⁻ layers 7 located at positions spaced apart from the gate electrode 5 by a predetermined distance, the P⁺ layers 9 (see FIG. 4) are formed. After the annealing step, interlayer insulating films, plug electrodes, metal wires, and the like, which are not shown in the figure, are formed, thereby forming the semiconductor device 200 shown in FIG. 4.

In this manufacturing method of this semiconductor device 200, since the step of implanting the N⁺ ions into the silicon substrate 1 and the step of forming the gate insulating film 23 are carried out by forming the silicon oxynitride film (SiON), compared to the manufacturing method of the semiconductor device 100, the number of steps can be advantageously decreased.

As described above, in this semiconductor device 200, a silicon oxynitride film (SiON) is used for the gate insulating film 23. Accordingly, even when B⁺ ions are contained in the gate electrode 5, the diffusion of the B⁺ ions from the gate electrode 5 into the silicon substrate 1 can be suppressed to a certain extent by the N⁺ ions present in the gate insulating film 23 (SiON).

In the second embodiment described above, as a method for introducing N⁺ ions into the silicon substrate 1, a case is described in which the silicon oxynitride film (SiON) 23 is used; however, the method is not limited thereto. For example, this silicon oxynitride film 23 may be used together with the ion implantation of N⁺ ions described in the first embodiment for implanting N⁺ ions into the silicon substrate 1. In this case, the N⁺ ions may be more efficiently introduced into the silicon substrate 1.

In addition, in the first and the second embodiments of the present invention, a case in which N⁺ ions are used as an impurity for suppressing diffusion is described; however, the impurity is not limited thereto. For example, F⁺ ions may also be used as an impurity for suppressing diffusion. Furthermore, the specific impurity of the present invention is not limited to B⁺ ions, and for example, BF₂⁺ ions may also be used.

In the semiconductor device 100 or 200 having an LDD structure, by introducing N⁺ ions or F⁺ ions into the P⁻ layers 7 formed of B⁺ ions or BF₂⁺ ions, the diffusion of the P⁻ layers 7 in the lateral direction (X-Y direction) and the depth direction (Z direction) can be suppressed to a certain extent.

### Advantages

As described above, according to the present invention, in the first impurity diffusion layers formed by introducing the specific impurity into the semiconductor layer at the two sides of the gate electrode, the diffusion suppression impurity for suppressing the diffusion of the specific impurity into the semiconductor layer is introduced, and hence the diffusion of the first impurity diffusion layers in the lateral direction and the depth direction can be suppressed.

Accordingly, the decrease in effective channel length caused by the diffusion of the first-impurity diffusion layers can be suppressed to a certain extent, and as a result, the short channel effect can be suppressed. Hence, progress in microfabrication of semiconductor devices can be further achieved.

What is claimed is:

1. A semiconductor device comprising:
a gate insulating film provided on a semiconductor layer;
a gate electrode provided on the gate insulating film; and
a source region and a drain region provided in the semiconductor layer at two sides of the gate electrode;
wherein the source and the drain regions comprise:
first impurity diffusion layers formed of a specific impurity introduced in the semiconductor layer adjacent two sides of the gate electrode; and
second impurity diffusion layers provided in the semiconductor layer adjacent the first impurity diffusion layers and opposite from the gate electrode, the second impurity diffusion layers being in contact with the first impurity diffusion layers; and
wherein the first impurity diffusion layers comprise:
a diffusion suppression impurity for suppressing diffusion of the specific impurity into the semiconductor layer.

2. The semiconductor device according to claim 1, wherein the diffusion suppression impurity is located in the semiconductor layer under the gate electrode.

3. A method for manufacturing a semiconductor device, comprising:
a step of forming a gate insulating film on a semiconductor layer;
a step of forming a gate electrode on the gate insulating film;
a step of introducing a diffusion suppression impurity into the semiconductor layer using the gate electrode as a mask, the diffusion suppression impurity suppressing diffusion of a specific impurity into the semiconductor layer;
a step of introducing the specific impurity into the semiconductor layer in which the diffusion suppression impurity had been introduced to form first impurity diffusion layers; and
a step of introducing another impurity into regions of the first impurity diffusion layers of the semiconductor layer to form second impurity diffusion layers, the regions each being spaced apart from the gate electrode by a predetermined distance.

4. A method for manufacturing a semiconductor device, comprising:
a step of introducing a diffusion suppression impurity for suppressing diffusion of a specific impurity into a semiconductor layer and forming a gate insulating film on the semiconductor layer;
a step of forming a gate electrode on the gate insulating film;
a step of introducing the specific impurity into the semiconductor layer using the gate electrode as a mask to form first impurity diffusion layers; and
a step of introducing another impurity into regions of the first impurity diffusion layers of the semiconductor layer to form second impurity diffusion layers, the regions each being spaced apart from the gate electrode by a predetermined distance.

5. The method for manufacturing a semiconductor device according to claim 4, wherein the step of introducing a diffusion suppression impurity into a semiconductor layer and forming a gate insulating film thereon further comprises a step of forming a gate insulating film containing the diffusion suppression impurity on the semiconductor layer so as to diffuse the diffusion suppression impurity into the semiconductor layer.

6. A semiconductor device comprising:
a gate insulating film provided on a semiconductor layer;
a gate electrode provided on the gate insulating film; and
a source region and a drain region provided in the semiconductor layer along two sides of the gate electrode;
wherein the source and drain regions comprise:
first impurity diffusion layers adjacent the two sides of the gate electrode, the first impurity diffusion layers including a specific impurity; and
second impurity diffusion layers abutting the first impurity diffusion layers opposite the gate electrode; and
wherein the specific impurity diffusion layers comprise:
a diffusion suppression impurity that suppresses diffusion of the specific impurity into the semiconductor layer.
